(19) United States
(12) Patent Application Publication
(10) Pub. No.: US 2008/0012063 A1
(43) Pub. Date: Jan. 17, 2008

(54) Flash Memory and Method for Manufacturing the Same

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/777,021

(22) Filed: Jul. 12, 2007

(30) Foreign Application Priority Data
Jul. 12, 2006 (KR) 10-2006-0065398

(51) Int. Cl. H01L 29/788; H01L 21/3205

(52) U.S. Cl. 257/316; 438/593; 257/E29.3; 257/E21.294

(57) ABSTRACT

A flash memory device can have a cell area and a periphery area. In a method for manufacturing the flash memory, a substrate of the cell area is etched by a predetermined depth, a first poly-silicon layer and an ONO layer are formed on the substrate of the cell area, and a second poly-silicon layer is formed on both the ONO layer of the cell area and a substrate of the periphery area.

### CROSS-REFERENCE TO RELATED APPLICATION

The present application claims the benefit under 35 U.S.C. §119 of Korean Patent Application No. 10-2006-0065398, filed Jul. 12, 2006, which is hereby incorporated by reference in its entirety.

### BACKGROUND

A flash memory is a nonvolatile memory that does not lose data stored therein even if power is turned off. In addition, flash memory provides a relatively high data processing speed for recording, reading, and deleting data. Accordingly, flash memory is widely used for Bios of a personal computer (PC), set-top boxes, printers, and network servers in order to store data. Recently, flash memory is widely used for digital cameras and portable phones.

FIG. 1 is a schematic view showing a related art flash memory.

As shown in FIG. 1, the related art flash memory is divided into a cell area and a periphery area. The cell area is provided to write and delete data, and the periphery area is provided to operate a transistor according to the data write and delete operation.

Isolation layers 2 are formed in the cell and periphery areas on a substrate 1.

A first poly-silicon layer 4, an ONO layer 5, and a second poly-silicon layer 6 are formed on the substrate 1 of the cell area, and the second poly-silicon layer 6 is formed on the substrate 1 of the periphery area.

In the cell area, the first poly-silicon layer 4 is used for a floating gate, and the second poly-silicon layer 6 is used for a control gate. In the periphery area, the second poly-silicon layer 6 is used for a gate.

As described above, since the cell area further includes the ONO layer 5 and the first poly-silicon layer 4 as compared with the periphery area, a step difference d occurs between the cell area and the periphery area by the thickness of the ONO layer 5 and the first poly-silicon layer 4 when a pre-metal dielectric (PMD) material 8 is deposited on the substrate 1.

A chemical mechanical polishing (CMP) process is performed with respect to the PMD material 8, so that a planarized inter-layer dielectric layer is obtained.

However, the PMD material 8 deposited on the substrate 1 is not planarized well through the CMP process due to the step difference d between the cell area and the periphery area.

In other words, when the CMP process is performed with respect to the PMD material 8, only the PMD material 8 in the cell area must be polished. However, since the PMD materials 8 in the cell area and the periphery area are actually polished at the same time, the uniformity of the inter-layer dielectric layer deteriorates after the CMP process. For this reason, although the CMP process is performed, contact defects may be caused due to the differential thickness between the cell area and the periphery area.

Particularly, as flash memory becomes more highly integrated, the non-uniformity between the cell area and the periphery area exerts a bad influence on device characteristics.

In FIG. 1, reference numerals 3, 7, and 9 represent an oxide layer, a spacer, and an impurity area, respectively.

### BRIEF SUMMARY

Accordingly, embodiments provide a flash memory and a method for manufacturing the same, capable of improving the uniformity of a substrate by etching the substrate of a cell area.

In an embodiment, there is provided a method for manufacturing a flash memory including a cell area and a periphery area, comprising etching a substrate of the cell area by a predetermined depth, forming a first poly-silicon layer and an ONO layer on the substrate of the cell area, and forming a second poly-silicon layer on the ONO layer of the cell area and a substrate of the periphery area.

According to an embodiment, there is provided a flash memory comprising a substrate divided into a cell area and a periphery area, a first poly-silicon layer and an ONO layer on the substrate of the cell area, and a second poly-silicon layer on the ONO layer of the cell area and the substrate of the periphery area, wherein the substrate of the cell area is lower than the substrate of the periphery area by a predetermined height.

### BRIEF DESCRIPTION OF THE DRAWINGS

FIG. 1 is a schematic view showing a related art flash memory; and

FIGS. 2A to 2H are views showing manufacturing steps for a flash memory according to an embodiment.

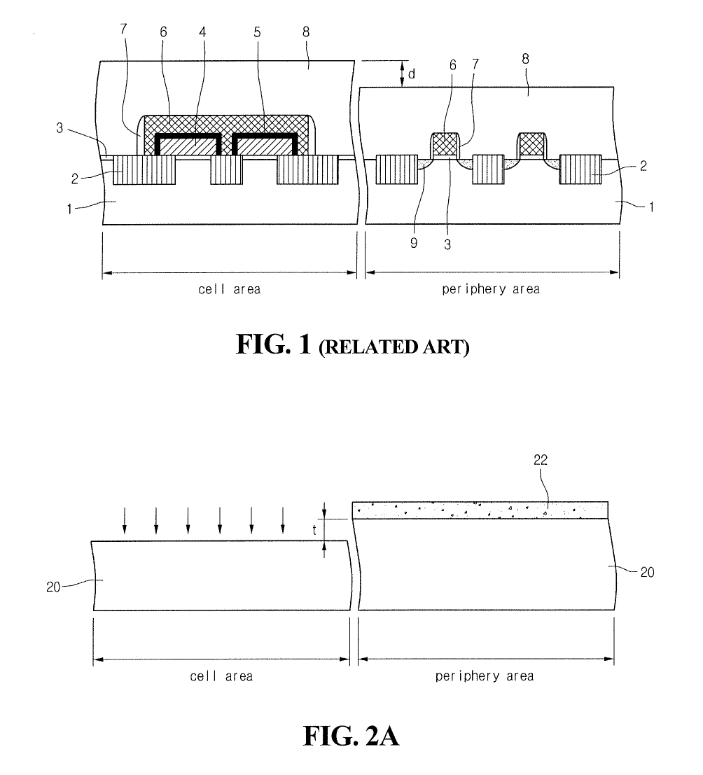

### DETAILED DESCRIPTION

Hereinafter, embodiments will be described with reference to the accompanying drawings.

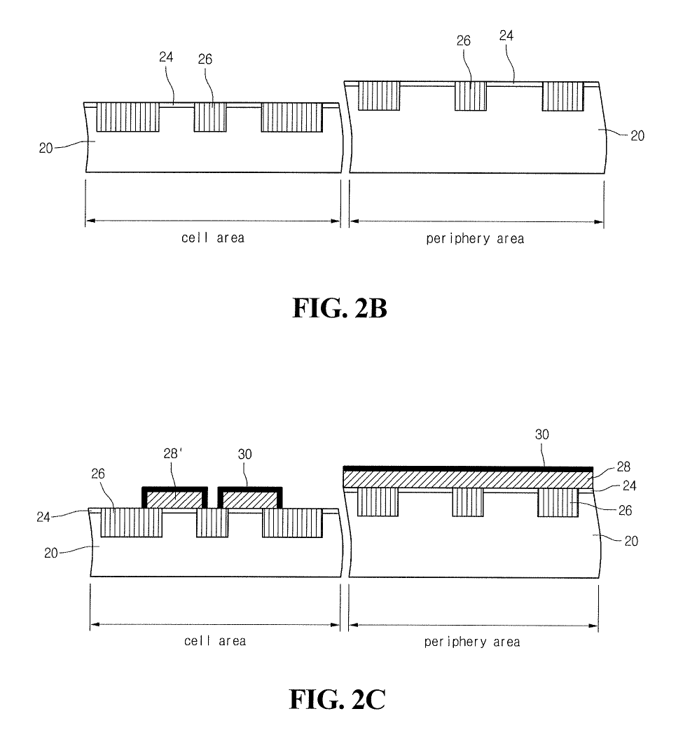

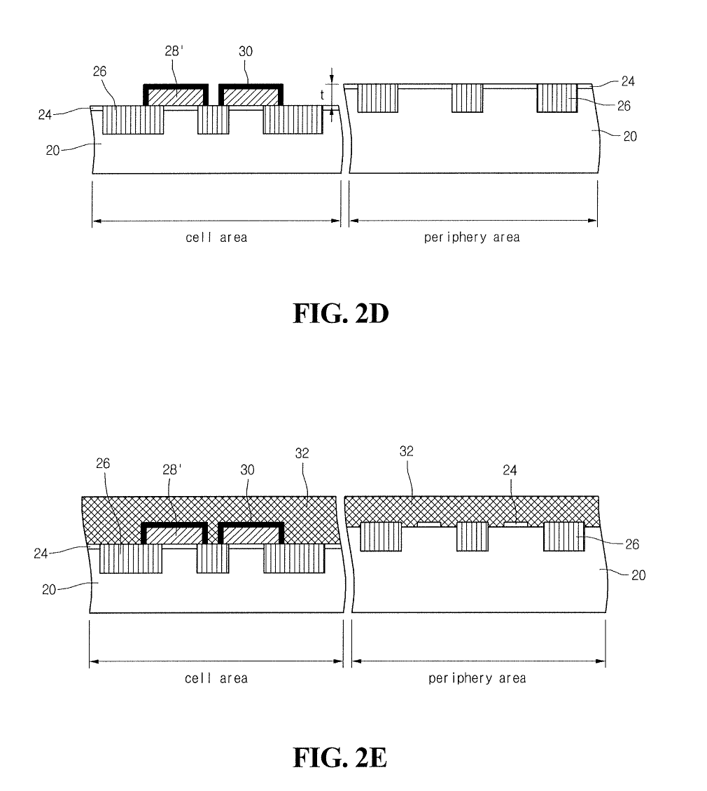

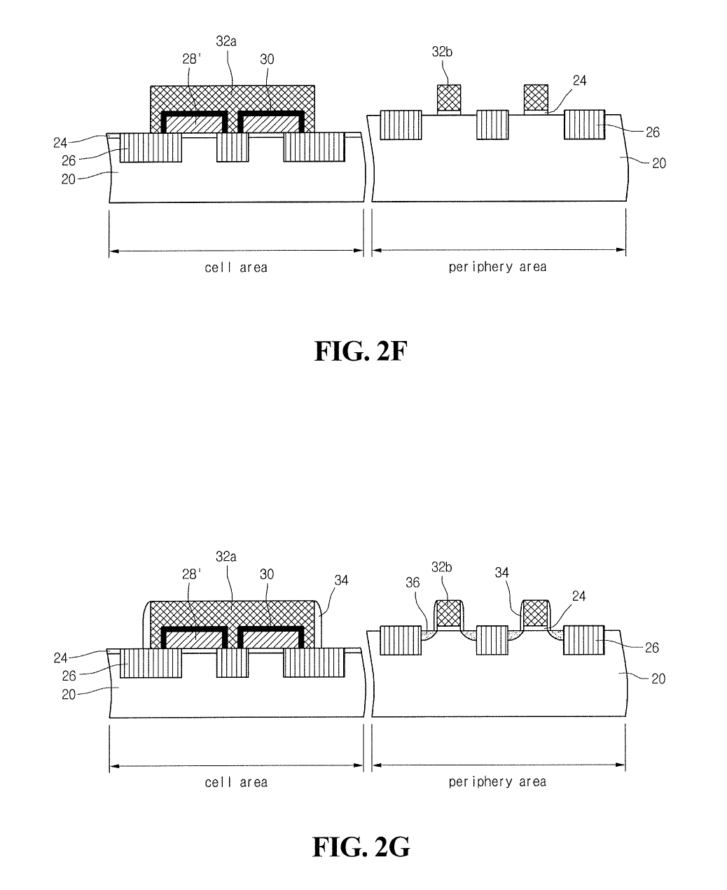

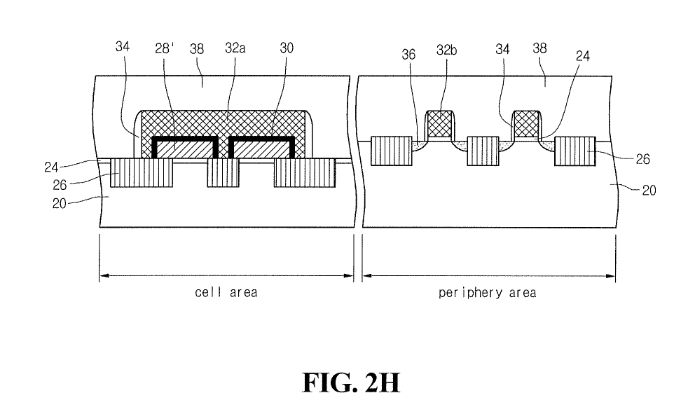

FIGS. 2A to 2H are views showing process steps of manufacturing a flash memory according to an embodiment.

As shown in FIG. 2A, a substrate 20 can be prepared, and divided into a cell area and a periphery area. A mask layer 22 can be deposited on the substrate 20, and portions of the mask layer 22 in the cell area can be removed from the substrate 20 while remaining in the periphery area. In one embodiment, the mask layer 22 can be a photoresist film.

An etching process is performed by using the mask layer 22, as an etch mask to etch the substrate 20 of the cell area by a predetermined depth t. Accordingly, a step difference occurs between the substrate 20 of the cell area and the substrate 20 of the periphery area by the depth t. In other words, the surface of the substrate 20 of the cell area becomes lower than the surface of the substrate 20 of the periphery area by the depth t.

The mask layer 22 is removed from the substrate 20 of the periphery area after the etching process.

As shown in FIG. 2B, isolation layers 26 and an oxide layer 24 can be formed on the substrate 20. In one embodiment, the isolation layers 26 and the oxide layer 24 can be formed by first forming an oxide layer and a nitride layer on the substrate 20, and depositing and patterning a predetermined mask material. Thereafter, an etching process can be performed to etch the substrate 20 using a mask pattern for isolation regions. Then, the mask pattern can be removed.

A gap filling process can be performed with respect to the substrate 20 with a predetermined insulating material, and then a trench CMP process can be performed to form the isolation layers 26 on the substrate 20. The isolation layers 26 are used to insulate various devices to be formed later on the substrate 20 from each other.

Thereafter, the nitride layer is removed from the substrate 20, and the isolation layer 26 and the oxide layer 24 remain on the substrate. The oxide layer 24 is formed on the substrate 20 between the isolation layers 26.

Although not shown in FIG. 2B, an ion implantation process can be selectively performed with respect to the substrate 20 including the isolation layers 26, so that a P-type well and an N-type well can be formed on the substrate 20.

As shown in FIG. 2C, a poly-silicon layer can be deposited on an entire surface of the substrate 20, and a patterning process can be performed with respect to the substrate 20 of the cell area to form a first poly-silicon layer 28′. The first poly-silicon layer 28′ can be used as a floating gate. The first poly-silicon layer 28′ is isolated on the substrate 20 between the oxide layer 24 and an ONO layer 30, and can be doped with dopants to have electric charges (electrons) such that the first poly-silicon layer 28′ remains in an excited state.

After forming the first poly-silicon layer 28′, an oxide layer, a nitride layer, and an oxide layer can be sequentially stacked on the entire surface of the substrate 20, and an annealing process can be performed with respect to the resultant structure. Then, a patterning process can be performed with respect to the substrate 20 of the cell area to form the ONO layer 30 surrounding the first poly-silicon layer 28′ as shown in FIG. 2C. The ONO layer 30 insulates an upper portion thereof from the lower portion thereof In other words, the ONO layer 30 insulates the first poly-silicon layer 28′ from a second poly-silicon layer which is described later.

In an embodiment illustrated in FIG. 2C, the poly-silicon layer 28 used in forming the first poly-silicon layer 28′ and the ONO layer 30 can remain on the substrate 20 of the periphery area after forming the structure in the cell area.

Accordingly, a predetermined mask material can be deposited on the entire surface of the substrate 20 and patterned to remove the mask material of the periphery area such that the mask layer remains only on the substrate 20 of the cell area.

Using the mask layer as an etch mask, the poly-silicon layer 28 and the ONO layer 30 formed on the substrate 20 of the peripheral area can be removed.

As shown in FIG. 2D, the depth t formed by the step difference between the substrate 20 of the cell area and the substrate 20 of the periphery area is substantially equal to the total thickness of the poly-silicon layer 28′ and the ONO layer 30 formed on the substrate 20 of the cell area. Generally, since the ONO layer 30 is very thin, the depth t of the step difference can be substantially equal to the thickness of the first poly-silicon layer 28′.

Accordingly, the substrate 20 of the cell area can be etched by the thickness t corresponding to the thickness of the first poly-silicon layer 28′. In a further embodiment, the substrate 20 of the cell area can be slightly more etched by taking the thickness of the ONO layer 30 into consideration.

Referring to FIG. 2E, a predetermined poly-silicon layer 32 can be deposited on the entire surface of the substrate 20 including the cell area and the periphery area. In an embodiment, since the surface of the ONO layer 30 formed on the substrate 20 of the cell area has a height substantially equal to the height of the surface of the substrate 20 of the periphery area, the poly-silicon layer 32 can be deposited on the entire surface of the substrate 20 including the cell area and the periphery area with the same thickness.

In an embodiment, before the poly-silicon layer 32 is deposited, portions of the oxide layer 24 may be selectively removed from the substrate 20 of the periphery area. An implantation process, which is described later, can be performed with respect to a portion of the substrate 20, which is exposed by the removed oxide layer 24 to form an impurity area on the substrate 20.

As shown in FIG. 2F, a patterning process can be performed with respect to the poly-silicon layer 32 to form second poly-silicon layers 32a and 32b.

The second poly-silicon layer 32a formed on the substrate 20 of the cell area covers the ONO layer 30, and the second poly-silicon layer 32b formed on the substrate 20 of the periphery area is formed in the area for a gate between the isolation layers 26. The second poly-silicon layer 32a formed on the substrate 20 of the cell area can be used as a control gate, and the second poly-silicon layer 32b formed on the substrate 20 of the periphery area can be used as a gate.

The second poly-silicon layer 32a formed on the substrate 20 of the cell area applies a bias voltage in order to perform a charging operation or a discharging operation by exciting electrons of the first poly-silicon layer 28′ positioned below the second poly-silicon layer 32a.

As shown in FIG. 2G, spacers 34 can be formed at the sidewalls of the second poly-silicon layers 32a and 32b, and an ion implantation process can be performed using the second poly-silicon layers 34a and 32b and the spacers 34 as implantation masks to form impurity areas 36 in the substrate 20. The impurity areas 36 can function as source and drain areas.

As shown in FIG. 2H, a PMD material 38 can be deposited on the substrate 20. In this case, the substrate 20 of the cell area is previously etched by a predetermined depth, so that the step difference between the cell area and the periphery area is reduced. Accordingly, the PMD material 38 is deposited on both the substrate 20 of the cell area and the substrate 20 of the periphery area with the same thickness, so that the uniformity of the substrate 20 can be improved.

Subsequently, the PMD material 38 is selectively etched to form an inter-layer dielectric layer having contact holes. Thereafter, contacts can be formed in the contact holes.

Accordingly, the flash memory can be completely manufactured.

As described above, description about some processes are omitted, however these processes are well-known or within the purview of one of ordinary skill in the art.

As described above, according to embodiments, the substrate of the cell area is etched before manufacturing the device, so that the step difference between the cell area and the periphery area is reduced. Accordingly, the uniformity can be improved, so that device characteristics can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a flash memory comprising:
etching a portion of a substrate in a cell area by a predetermined depth;
forming a first poly-silicon layer pattern and an ONO layer on the etched portion of the substrate in the cell area; and
forming a second poly-silicon layer pattern on the ONO layer of the cell area and on the substrate of a periphery area.

2. The method according to claim 1, wherein the predetermined depth has a total thickness of the first poly-silicon layer pattern and the ONO layer.

3. The method according to claim 1, wherein the predetermined depth has a thickness of the first poly-silicon layer pattern.

4. The method according to claim 1, wherein a top surface of the ONO layer in the cell area has the same height as the substrate of the periphery area.

5. The method according to claim 1, wherein the first poly-silicon layer pattern in the cell area is a floating gate, and the second poly-silicon layer pattern in the cell area is a control gate.

6. The method according to claim 1, wherein the second poly-silicon layer pattern in the periphery area is a gate.

7. The method according to claim 1, wherein etching the portion of the substrate in the cell area comprises:
forming a mask layer on the substrate of the periphery area; and
etching the substrate of the cell area using the mask layer as an etching mask.

8. The method according to claim 7, wherein the mask layer comprises a photoresist film.

9. A flash memory comprising:
a substrate having a cell area and a periphery area;
a first poly-silicon layer pattern and an ONO layer on the first poly-silicon pattern on the substrate of the cell area; and
a second poly-silicon layer pattern on the ONO layer of the cell area and the substrate of the periphery area, wherein the substrate of the cell area is lower than the substrate of the periphery area by a predetermined height.

10. The flash memory according to claim 9, wherein the predetermined height has a total thickness of the first poly-silicon layer pattern and the ONO layer.

11. The flash memory according to claim 9, wherein the predetermined height has a thickness of the first poly-silicon layer pattern.

12. The flash memory according to claim 9, wherein a top surface of the ONO layer in the cell area has the same height as the substrate of the periphery area.

13. The flash memory according to claim 9, wherein the first poly-silicon layer pattern in the cell area is a floating gate, and the second poly-silicon layer pattern in the cell area is a control gate.

14. The flash memory according to claim 1, wherein the second poly-silicon layer pattern in the periphery area is a gate.
